(19) United States
(12) Patent Application Publication
(10) Pub. No.: US 2008/0305561 A1
(43) Pub. Date: Dec. 11, 2008

(54) Methods of controlling film deposition using atomic layer deposition

(76) Inventor: Shrinivas Govindarajan, Glen Allen, VA (US)

Correspondence Address: SLATER & MATSIL, L.L.P., 17950 PRESTON ROAD, SUITE 1000, DALLAS, TX, 75252, US

(21) Appl. No.: 11/810,721

(22) Filed: Jun. 7, 2007

(51) Int. Cl. H01L 21/31; B23P 19/00; H01L 21/66; H01L 21/8242

(52) U.S. Cl. 438/7; 118/715; 438/239; 438/763; 257/E21.24; 257/E21.529; 257/E21.646

(57) ABSTRACT

Methods of manufacturing semiconductor devices and structures thereof are disclosed. A preferred embodiment comprises a method of forming a material layer. The method includes providing a semiconductor wafer, forming a first portion of a material layer over the semiconductor wafer at a first pressure, and forming a second portion of the material layer over the first portion of the material layer at a second pressure, the second pressure being less than the first pressure.

### TECHNICAL FIELD

The present invention relates generally to the fabrication of semiconductors, and more particularly to the formation of material layers using atomic layer deposition (ALD) processes.

### BACKGROUND

Generally, semiconductor devices are used in a variety of electronic applications, such as computers, cellular phones, personal computing devices, and many other applications. Home, industrial, and automotive devices that in the past comprised only mechanical components now have electronic parts that require semiconductor devices, for example.

Semiconductor devices are manufactured by depositing many different types of material layers over a semiconductor workpiece or wafer, and patterning the various material layers using lithography. The material layers typically comprise thin films of conductive, semiconductive, and insulating materials that are patterned and etched to form integrated circuits (IC's). There may be a plurality of transistors, memory devices, switches, conductive lines, diodes, capacitors, logic circuits, and other electronic components formed on a single die or chip.

Material layers of semiconductor devices are formed using a variety of types of processes. Material layers may be formed using chemical vapor deposition (CVD), physical vapor deposition (PVD), jet vapor deposition (JVD), epitaxial growth processes, oxidization processes, or nitridation processes, as examples. One type of deposition process for semiconductor devices is atomic layer deposition (ALD), wherein very thin layers are sequentially formed.

ALD is a surface chemistry process in which conformal thin films of materials are successively deposited onto a substrate or workpiece. ALD is similar in chemistry to CVD, except that the ALD reaction breaks a CVD reaction into two half-reactions, by keeping the precursor materials separate during the reaction. ALD film growth is self-limited and is based on surface reactions, which makes achieving atomic scale deposition control possible.

ALD has unique advantages over other thin film deposition techniques, as ALD grown films may result in conformal material layers that are chemically bonded to the substrate, in some applications. However, ALD processes in some applications may result in film growth that is not in a completely saturated mode, which may promote island growth or may result in a combination of island and layer-by-layer growth, resulting in thickness non-uniformities. Initial thickness non-uniformities may result in eventual step coverage of a final ALD film that is less than 100%, for example.

Thus, what are needed in the art are improved ALD processes for semiconductor devices.

### SUMMARY OF THE INVENTION

These and other problems are generally solved or circumvented, and technical advantages are generally achieved, by preferred embodiments of the present invention, which provide novel manufacturing methods and structures thereof, wherein step coverage of ALD processes is optimized.

In accordance with a preferred embodiment of the present invention, a method of forming a material layer includes providing a semiconductor wafer, and forming a first portion of a material layer over the semiconductor wafer at a first pressure. A second portion of the material layer is formed over the first portion of the material layer at a second pressure, the second pressure being less than the first pressure.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a flow chart illustrating a method of forming a material layer in accordance with a preferred embodiment of the present invention;

FIGS. 2 through 7 show cross-sectional views of a semiconductor device in accordance with embodiments of the present invention at various stages of manufacturing;

FIGS. 8 and 9 show cross-sectional views of a semiconductor device at various stages of manufacturing, wherein the novel methods of forming material layers of embodiments of the present invention are implemented in a metal-insulator-metal (MIM) capacitor structure;

FIG. 10 shows a cross-sectional view of a semiconductor device, wherein the novel methods of forming material layers of embodiments of the present invention are implemented in a transistor structure; and

FIGS. 11 and 12 show cross-sectional views of a semiconductor device at various stages of manufacturing, wherein the novel methods of forming material layers of embodiments of the present invention are implemented in a DRAM structure.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

ALD is often used to deposit dielectric and metal layers on planar semiconductor surfaces or in structures such as trench or stacked capacitors. One ALD cycle typically comprises pulsing a precursor, purging the precursor, pulsing a reactant, purging the reactant, and pulsing and purging additional precursors and reactants if appropriate. ALD cycles are repeated until the desired thickness of a material layer is achieved. The ALD cycles are typically optimized using flat wafers, for achieving self-limiting growth and good uniformity.

However, if the initial film nucleation or growth does not completely saturate the surface, island growth or a combination of island and layer-by-layer growth may result, causing thickness non-uniformities. Such initial thickness non-uniformities may result in eventual step coverage of a final material that is less than 100%, resulting in decreased device performance, device failures, and decreased yields.

Embodiments of the present invention achieve technical advantages by providing novel processing solutions for the formation of continuous material layers having improved step coverage using ALD processes. The present invention will be described with respect to preferred embodiments in specific contexts, namely in the formation of dielectric materials in semiconductor devices such as capacitors and transistors. Embodiments of the present invention may also be applied, however, to the formation of dielectric materials in other applications, to the formation of conductive material layers, or to the formation of other thin layers of materials where continuous coverage is desired, for example.

Embodiments of the present invention achieve technical advantages by improving the initial film formation of ALD processes, which functions as a template for subsequent growth of the film. A novel initial high pressure template formation deposition step comprising one or more ALD deposition cycles is used before subsequent ALD cycles are performed, that achieve a target thickness and uniformity of a material layer. During the novel template formation step, the residence time of the precursor or precursors and reactants is preferably maximized to ensure complete reaction and surface saturation.

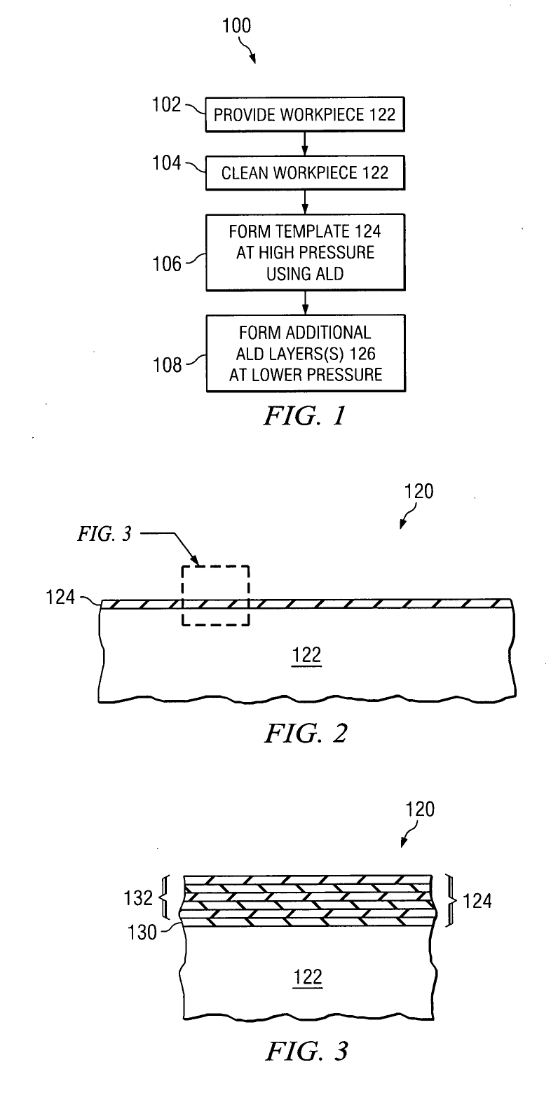

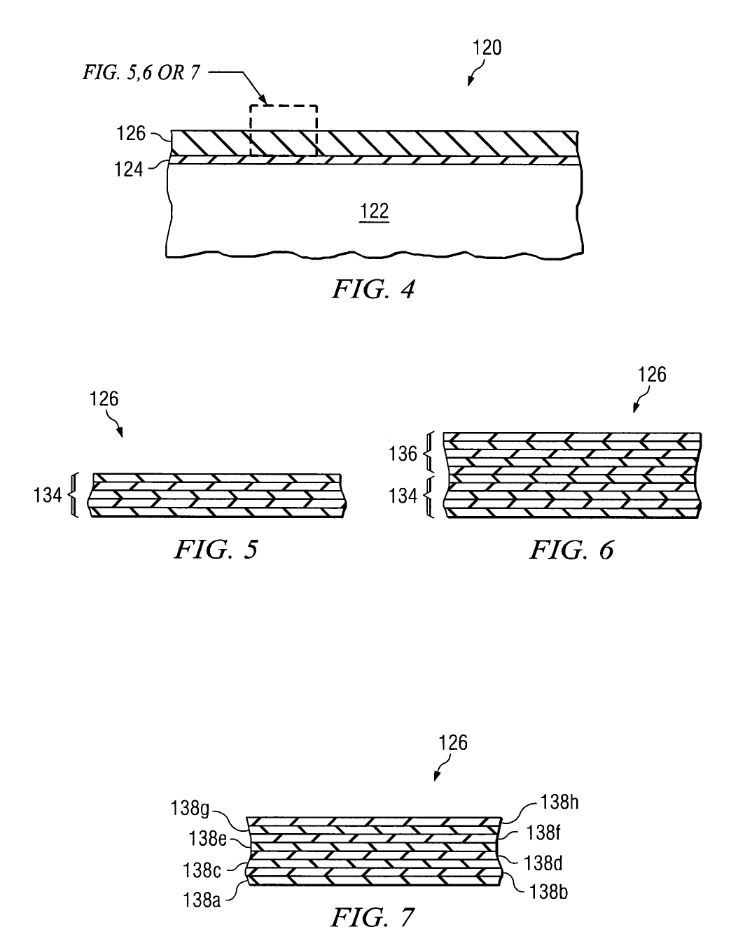

FIG. 1 is a flow chart 100 illustrating a method of forming a material layer 124/126 of a semiconductor device 120 (see FIG. 4) in accordance with a preferred embodiment of the present invention. FIGS. 2 through 7 show cross-sectional views of a semiconductor device 120 in accordance with embodiments of the present invention at various stages of manufacturing, wherein the material layer 124/126 is formed on a planar semiconductor device 120.

Referring to the flow chart 100 in FIG. 1 and also to the semiconductor device 120 shown in FIG. 2, first, a workpiece 122 is provided (step 102). The workpiece 122 may include a semiconductor substrate or wafer comprising silicon or other semiconductor materials covered by an insulating layer, for example. The workpiece 122 may also include other active components or circuits, not shown. The workpiece 122 may comprise silicon oxide over single-crystal silicon, for example. The workpiece 122 may include other conductive layers or other semiconductor elements, e.g., transistors, diodes, etc. Compound semiconductors, GaAs, InP, Si/Ge, or SiC, as examples, may be used in place of silicon. The workpiece 122 may comprise a silicon-on-insulator (SOI) or germanium-on-insulator (GOI) substrate, for example.

The workpiece 122 is cleaned (step 104). For example, the workpiece 122 may be cleaned to remove debris or contaminants. In a preferred embodiment, the workpiece 122 is cleaned with hydrofluoric acid (HF) to remove native oxide, followed by an oxidizing cleaning process, such as an SC1 cleaning process, for example, which may result in the formation of a chemical oxide layer. Alternatively, other cleaning methods and chemistries may also be used. The cleaning step 104 preferably results in a good interface that facilitates the subsequent deposition of a material layer thereon, for example. The cleaning step 104 may result in the formation of a thin oxide layer over the workpiece 122 comprising an oxide material such as silicon dioxide (SiO₂) having a thickness of about 10 Angstroms or less, not shown.

Next, a template 124 is formed over the workpiece 122, as shown in FIG. 2 (step 106 of FIG. 1). FIG. 3 shows a more detailed view of the template 124 shown in FIG. 2. The template 124 is also referred to herein as a first portion 124 of a material layer 124/126, for example.

The template 124 is preferably formed by forming a first layer 130 over workpiece using a first ALD process at a high pressure. The pressure of the first ALD process is also referred to herein as a first pressure. The first pressure may comprise about 0.15 to 100 Torr, for example, although alternatively, the first pressure may comprise other amounts.

The template 124 may comprise only the first layer 130 in some embodiments, for example. The template 124 may optionally also comprise at least one second layer 132 formed over the first layer 130, wherein the at least one second layer 132 is also formed using the first ALD process at the first pressure. The first layer 130 and the at least one second layer 132 preferably comprise the same material, for example, in some embodiments. The first layer and the at least one second layer 132 may comprise different materials, in other embodiments.

The first layer 130 and the at least one second layer 132 of the template 124 may comprise a dielectric material or insulator, as an example. The first layer 130 and the at least one second layer 132 of the template may alternatively comprise a conductor, as another example.

The first layer 130 and the at least one second layer 132 of the template 124 may comprise a sub-monolayer, a monolayer, or a plurality of monolayers of a material, for example. The first layer 130 and the at least one second layer 132 of the template 124 may comprise a thickness of about 0.5 to 10 Angstroms, for example, although alternatively, the first layer 130 and the at least one second layer 132 of the template 124 may comprise other dimensions.

Advantageously, the high pressure of the template 124 formation ALD process preferably results in a substantially continuous, conformal coverage of the workpiece 122 surface, resulting in an island-free template 124. Because the template 124 is continuous and island-free, the formation of subsequent materials over the template 124 is improved, such as layer 126 shown in FIG. 4.

Next, a second ALD process (step 108 in FIG. 1) at a lower pressure is used to form a layer 126 over the template 124, as shown in FIG. 4. The pressure of the second ALD process is also referred to herein as a second pressure, wherein the second pressure is less than the first pressure of the first ALD process. The first pressure of the first ALD process used to form the template 124 is preferably about ten times (10×) or greater than the second pressure of the second ALD process to form layer 126, for example. More preferably, in some embodiments, the first pressure may be about 100 times greater than the second pressure, as another example. Layer 126 is also referred to herein as a second portion 126 of a material layer 124/126, for example. FIGS. 5, 6, and 7 show more detailed cross-sectional views of the layer 126 of preferred embodiments of the present invention.

In FIG. 5, the layer 126 preferably comprises a plurality of material layers 134 forming using the second ALD process at a single lower pressure, wherein the second pressure of the second ALD process is less than the first pressure of the first ALD process. The material layers 134 may comprise sub-monolayers, monolayers, or a plurality of monolayers of a material, for example. The material layers 134 may comprise a thickness of about 0.5 to 10 Angstroms, for example, although alternatively, the material layers 134 may comprise other dimensions.

In FIG. 6, an embodiment is shown wherein the layer 126 comprises a plurality of first material layers 134 formed at a second pressure using the second ALD process, the second pressure being less than the first pressure of the first ALD process used to form the template 124. The layer 126 also comprises a plurality of second material layers 136 formed at a third pressure, the third pressure being less than the second pressure used to form the first material layers 134 of layer 126. The plurality of first material layers 134 may comprise a second portion of the material layer 124/126, and the plurality of second material layers 136 may comprise a third portion of the material layer 124/126, in this embodiment.

The first and second material layers 134 and 136 may comprise sub-monolayers, monolayers, or a plurality of monolayers of a material, for example. The first and second material layers 134 and 136 may comprise a thickness of about 0.5 to 10 Angstroms, for example, although alternatively, the first and second material layers 134 and 136 may comprise other dimensions.

In yet another embodiment shown in FIG. 7, the layer 126 formed over the template 124 preferably comprises a plurality of material layers 138a, 138b, 138c, 138d, 138e, 138f, 138g, and 138h, wherein each of the material layers 138a, 138b, 138c, 138d, 138e, 138f, 138g, and 138h is formed using an ALD process having a successively lower pressure. For example, material layer 138a is preferably formed using an ALD process having a lower pressure than the first pressure of the first ALD process used to form the template 124. Material layer 138b is preferably formed using an ALD process having a lower pressure than the pressure of the ALD process used to form material layer 138a. Likewise, material layer 138c is formed using an ALD process having a lower pressure than the pressure of the ALD process used to form material layer 138b. The pressures are continued to be lowered with the deposition of each subsequent material layer 138d, 138e, 138f, 138g, and 138h formed, for example.

The number of layers 130, 132, 134, 136, and 138a through 138g of the template 124 and layer 126 of the embodiments shown in FIGS. 3, 5, 6, and 7 may vary according to the type of material layer 124/126 being formed and according to the desired thickness of the material layer 124/126, for example. The number of layers 130, 132, 134, 136, and 138a through 138g shown in the drawings is exemplary; however, different numbers of the various layers 130, 132, 134, 136, and 138a through 138g may also be used, for example. The number of layers 132, 134, 136, and 138a through 138g may range from about 1 to 50, for example, although other numbers of layers 132, 134, 136, and 138a through 138g may also be used depending on the desired properties of the material layer 124/126. The thickness of the material layer 124/126 may be modified by varying the number of cycles of ALD deposition for the various material layers 130, 132, 134, 136, and 138a through 138g, for example.

In some embodiments, the material layer 124/126 preferably comprises an insulator. The material layer 124/126 may comprise a high k dielectric material having a dielectric constant greater than about 3.9, for example. Alternatively, the material layer 124/126 may comprise a low k dielectric material having a dielectric constant of less than 3.9, as another example. The material layer 124/126 may comprise an oxide, nitride, or oxynitride of a single element or a plurality of elements, for example. The material layer 124/126 may comprise an insulating layer comprising a dielectric material having a single element combined with an oxide, a nitride, or both and oxide or a nitride, or a plurality of elements combined with an oxide, a nitride, or both an oxide and a nitride. The material layer 124/126 may comprise a single element oxide, a binary oxide, or an oxide of two or more species, for example. The material layer 124/126 may comprise an oxide of two or more different metals, as another example. The material layer 124/126 may comprise AlₓO_{y}, HfO₂, HfSiON, Al doped with ZrO₂, or Hf doped with GdO₂, as examples, although other types of insulating materials may also be used.

In other embodiments and applications, the material layer 124/126 may also comprise conductors such as TiN, TaCN, MoAlN, or HfTiN, for example, although other types of conductive materials may also be used. The material layer 124/126 may comprise a single component or a multiple component film, for example.

The manufacturing process for the semiconductor device 120 is then continued to complete the fabrication of the semiconductor device 120. The material layers 124/126 may be patterned into desired shapes for the semiconductor device 120, not shown. For example, if the material layer 124/126 is conductive, it may be patterned in the shape of a capacitor plate, a transistor gate, or other conductive elements or portions of circuit elements, as examples. Material layers 124/126 comprising insulators may also be patterned, for example.

The ALD processes used to form the material layers 124/126 may be performed in a tool comprising a reactor, for example. The residence time of the reactor comprises a ratio of the volume of the reactor to the volumetric flow rate. Reducing the volumetric flow rate is one way to increase the residence time of the reactor, for example. In accordance with an embodiment of the present invention, the volumetric flow rate is reduced by pressurizing the reactor, e.g., to the maximum level allowable by the reactor, precursor, and the process conditions, in some embodiments.

In one embodiment, a recipe based set point for the pressure of the reactor may be used to establish the first pressure of the first ALD processes used to form the template 124. In another embodiment, a set point may be provided for a throttle valve of the reactor that controls the pressure within the reactor, in order to close the valve and prevent leakage of precursors after setting the pressure, e.g., at a maximum level. In yet another embodiment, which may be used if direct control of the throttle valve setting is not possible, for example, the pressure may be set to a level that forces closure of the throttle valve and sets the step duration to a level that does not cause the tool to fault, for example.

From the kinetic theory of gases, the flux of molecules onto a surface, J, in molecules per unit area per unit time, is related to the partial pressure of the liquid precursor through the relationship shown in Equation 1:

J=P/(2πmkT)0.5; Eq. 1

wherein P is the partial pressure of precursor (e.g., the vapor pressure), m is the molecular mass of the precursor, k is Boltzmann's constant, and T is the temperature (K). In order to maximize the flux J, the three variables available to adjust are the vapor pressure P, the temperature T, and the molecular mass m of the precursor.

Because the temperature T is typically limited by the decomposition of the precursor and the potential for CVD reactions, and the molecular mass m of the precursor is generally fixed by cost, throughput, and availability, the only effective variable available to adjust is the increase of the partial pressure of the precursor, which is achieved by embodiments of the present invention.

The template 124 formation step preferably comprises introducing a first reactant into the reactor at the initial, higher pressure. The first reactant is introduced into the chamber of the reactor, pressure is set to the maximum possible level, and the throttle valve is closed, in order to maximize the residence time of the first reactant in the chamber. Then, a purge step is used to remove the first reactant from the chamber, which is preferably optimized to prevent either desorption/decomposition of the reaction products or of the reactant, e.g., if the purge is excessively long, or to prevent CVD reactions, e.g., if the purge duration is excessively short. A second reactant is then introduced in a similar fashion; e.g., the second reactant is introduced into the chamber, pressure is set to the maximum possible level, and the throttle valve is closed, in order to maximize the residence time of the second reactant in the chamber. A second purge step is used to remove the second reactant from the chamber, which is also preferably optimized to prevent either desorption/decomposition of the reaction products or of the reactant, e.g., if the purge is excessively long, or to prevent CVD reactions, e.g., if the purge duration is excessively short. This completes the template 124 formation cycle for pre-treatment of the surface of the workpiece 122 in accordance with embodiments of the present invention.

Depending on the precursor chemistry, in particular, the steric hindrance resulting from the size of the ligands, reactor design, wafer or workpiece 122 surface conditions (i.e., preparation steps), and process parameters, the template 124 formation cycle may need to be repeated several times until complete coverage of the workpiece 122 surface is achieved. However, in some embodiments, a single cycle for forming the template 124 is preferred, because multiple cycles may increase the tendency for non-uniform layer growth in some applications.

To verify complete coverage of the template 124, after the formation of the template 124, low energy ion spectroscopy (LEIS) or medium energy ion spectroscopy (MEIS) may be used to determine if the underlying substrate 122 signal is still detectable. Alternatively, X-ray fluorescence (XRF) may be used to determine or monitor the early film growth of the template 124, for example. The number of atoms of the template 124 material on the surface may be counted using these techniques, for example. After detecting whether or not the template 124 completely covers the workpiece 122, either one or more additional template 124 formation steps may be implemented at the higher pressure if the template 124 incompletely covers the workpiece 122, or the layer 126 may be formed over the template 124, if the template 124 is observed to completely cover the workpiece 122, for example. Obtaining a template 124 that comprises a single monolayer may be a goal in some embodiments, as an example.

In accordance with some embodiments of the present invention, the maximum attainable chamber pressure may be determined using unpatterned, planar semiconductor wafers or workpieces 122. The optimum step duration for the pulse and purge steps of the ALD processes used to form the template 124 may be determined, using LEIS or other methods to determine the condition that maximizes surface coverage, for example.

However, on patterned wafers 122, the exposure, i.e., pressure*time, measured in Langmuirs (1E-6 Torr·s) preferably is adjusted or increased, to account for the significant increase of surface area due to the presence of the patterned structures, for example. An estimate of the additional exposure required for wafers 122 having patterned structures may be obtained by calculating the ratio of surface area for the wafer 122 with and without patterned features (e.g., which may comprise trenches or stacks for capacitors) and by accounting for some losses due to deposition on the reactor walls, and to a predicted percentage of inefficiency, for example. After the template 124 formation cycle(s) is completed, normal processing of the wafer 122 may be resumed using standard ALD deposition cycles to form layer 126 over the template 124, in accordance with embodiments of the present invention.

Ensuring layer-by-layer film growth by optimization of the initial template 124 film nucleation and growth in accordance with embodiments of the present invention may advantageously result in the formation of a template 124 comprising a continuous monolayer, through control of precursor residence time during the initial stage of the template 124, for example.

In accordance with embodiments of the present invention, the parameters for the ALD processes are preferably optimized to achieve a continuous coverage of the workpiece 122 of the template 124 and the layer 126. For example, the parameters of the choice of precursors/reactants, the reactor temperature, process temperature, chamber pressure, duration and flow rates of precursors/reactants, substrate surface preparation, holding temperature of the precursor sources, and/or pulse and purge durations are preferably optimized in accordance with embodiments of the present invention for the formation of the template 124 and the layer 126 for optimal ALD growth.

As an example, in one embodiment, the material layer 124/126 may comprise a dielectric layer comprising Al₂O₃. Embodiments of the present invention may be implemented in ALD reactors such as Aviza, TEL, Vesta, or Aixtron ALD chambers, although other reactors may also be used. A commonly used precursor for aluminum metal is tri-methyl aluminum (TMA), for example. The other precursor or oxidant may comprise either H₂O or O₃, as examples. The operating temperature to form Al₂O₃ may comprise between about 200 to 550 degrees C. The chamber or reactor pressure preferably comprises about 0.15 to 100 Torr for the first pressure to form the template 124, and about 150 and 2000 mTorr for the second pressure to form the layer 126, as examples, in accordance with a preferred embodiment of the present invention.

In accordance with an embodiment of the present invention, in order to optimize the step coverage for Al₂O₃, the maximum chamber pressure attainable with different flow rates of the precursor and/or reactant is determined, and the time to fault is determined, if the desired pressure cannot be stabilized. The throttle position and behavior may be recorded for each condition. A residual gas analysis (RGA) testing machine may be used to monitor inlet and outlet compositions and develop residence time distribution curves. The precursor consumption efficiency may be determined from a mass balance, for example. The optimum purge duration for precursors and reactants may be determined. If the purge time is too short, there is the risk of CVD reactions between the two precursors; and if the purge time is too long, throughput is reduced and there is a possibility of desorption of reaction products from the substrate 122. The optimum setting may be determined either by using an RGA testing machine to monitor the reactions or through standard saturation curves, for example. Using the information acquired from these tests, the process parameters for the template 124 formation step may be determined, such as the pressure setting, flow rates and pulse and purge duration times, as examples.

Next, unpatterned wafers 122 may be tested with varying surface pre-treatments, e.g., to address incubation effects and interfacial film properties. The wafers 122 may be inserted into a susceptor or heater inside the reactor, for example. After allowing for temperature and pressure stabilization, the template 124 formation step may be initialized. A first precursor such as TMA may be introduced, pressurized, and held or pulsed for a required duration. The reactor is then purged, and the reactant (e.g., O₃ or H₂O) is introduced and held for the required duration. The reactor is then purged of the reactant. The wafer 122 is then removed and tested for surface coverage using LEIS, MEIS, or XRF, for example.

A plurality of tests may be performed, e.g., with an increasing number of template 124 formation ALD cycles, and the surface coverage may be characterized as a function of the number of ALD cycles, for example. The optimum number of cycles may then be determined, wherein the optimum number of cycles used to form the template 124 corresponds to conditions wherein surface coverage is maximized. Thus, a measure of the exposure required for flat, unpatterned wafers 122 may then be determined.

Next, in accordance with embodiments of the present invention, the same tests may be performed on patterned wafers 122 having a topography, e.g., recesses and protruding features, with the optimized surface pretreatment (e.g., the template 124 formed using a high pressure ALD process), in order to determine process parameters for achieving the best step coverage. The exposure for patterned wafers 122 is preferably larger than that required to saturate a flat wafer 122, for example. Depending on the topography of the wafers 122, about 30% of excess precursors may be used, e.g., with a provision included to increase or reduce this additional amount based on experimental data. In other embodiments of the present invention, the novel template 124 formation steps may be used to form other types of films, such as transition metal nitrides, rare earth nitrides, rare earth oxides, and other materials.

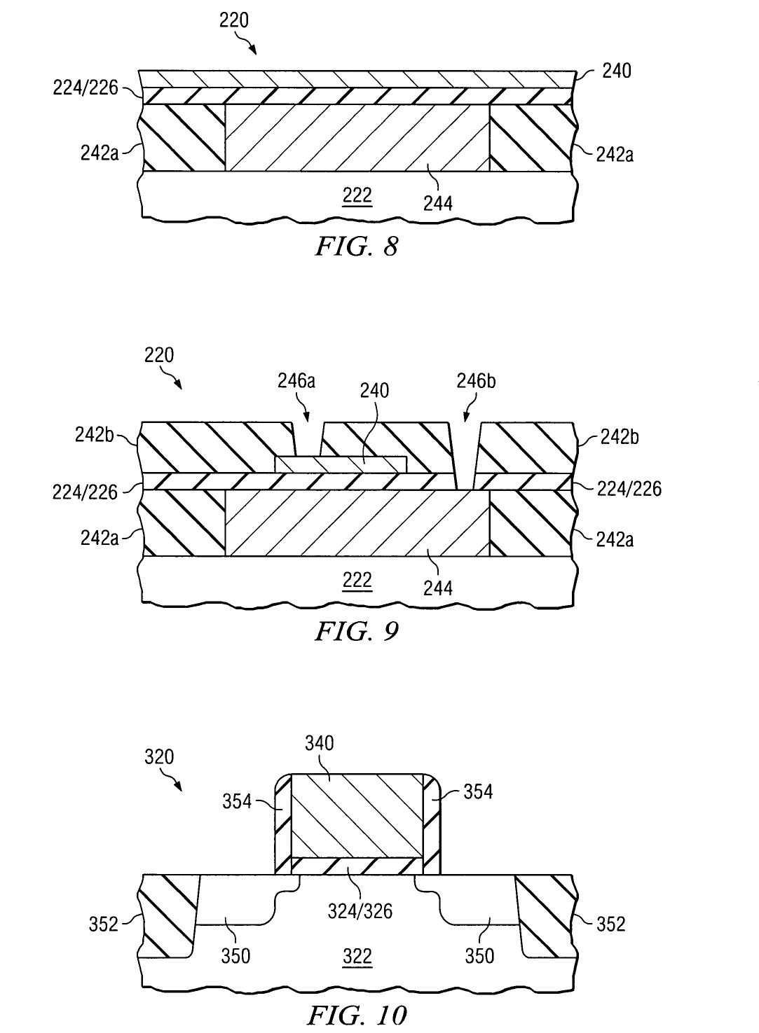

FIGS. 8 and 9 show cross-sectional views of a semiconductor device 220 at various stages of manufacturing, wherein the novel material 124/126 shown in FIGS. 2 through 7 of embodiments of the present invention is implemented in a metal-insulator-metal (MIM) capacitor structure, for example. Like numerals are used for the various elements that were used to describe FIGS. 2 through 7. To avoid repetition, each reference number shown in FIGS. 8 and 9 is not described again in detail herein. Rather, similar materials x22, x24, x26, etc. are preferably used for the various material layers shown as were used to describe FIGS. 2 through 7, where x=1 in FIGS. 2 through 7 and x=2 in FIGS. 8 and 9.

To form the MIM capacitor, a bottom capacitor plate 244 is formed over a workpiece 222. The bottom plate 244 may comprise a semiconductive material such as polysilicon, or a conductive material such as copper or aluminum, as examples. The bottom capacitor plate 244 may be formed in an insulating material 242a that may comprise an inter-level dielectric layer (ILD), for example. The bottom capacitor plate 244 may include liners and barrier layers, for example, not shown.

A high k dielectric material comprising a material layer 224/226 formed using the novel ALD processes described with reference to FIGS. 1 through 7 is formed over the bottom plate 244 and the insulating material 242a. An electrode material 240 is formed over the dielectric material 224/226, as shown in FIG. 8, and the electrode material 240 is patterned to form a top capacitor plate, as shown in FIG. 9. An additional insulating material 242b may be deposited over the top capacitor plate 240, and the insulating material 242b and also the material layer 224/226 may be patterned with patterns 246a and 246b for contacts that will make electrical contact to the top plate 240 and the underlying bottom plate 244, respectively. The insulating material 242b may be filled in later with a conductive material to form the contacts, for example, not shown.

Thus, in FIG. 9, a capacitor is formed that includes the two conductive plates 244 and 240 separated by an insulator which comprises the novel material layer 224/226 of embodiments of the present invention. The capacitor may be formed in a front-end-of the line (FEOL), or portions of the capacitor may be formed in a back-end-of the line (BEOL), for example. One or both of the capacitor plates 224 and 240 may be formed in a metallization layer of the semiconductor device 220, for example. Capacitors such as the one shown in FIG. 9 may be used in filters, in analog-to-digital converters, memory devices, control applications, and many other types of applications, for example.

Note that at least portions of the conductive plates 224 and 240 of a capacitor may also be formed using the novel methods described herein, not shown in the drawings.

FIG. 10 shows a cross-sectional view of a semiconductor device 320, wherein the novel material layer 324/326 of embodiments of the present invention is implemented in a transistor structure as a gate dielectric. Again, like numerals are used for the various elements that were used to describe the previous figures, and to avoid repetition, each reference number shown in FIG. 10 is not described again in detail herein.

The transistor includes a gate dielectric comprising the novel material layer 324/326 described herein and a gate electrode 340 formed over the material layer 324/326. Source and drain regions 350 are formed proximate the gate electrode 340 in the workpiece 322, and a channel region is disposed in the workpiece 322 between the source and drain regions 350. The transistor may be separated from adjacent devices by shallow trench isolation (STI) regions 352, insulating spacers 354 may be formed on sidewalls of the gate electrode 340 and the gate dielectric comprising the material layer 324/326, as shown.

Embodiments of the present invention have been described herein in semiconductor applications having planar structures that the material layers 124/126, 224/226, and 324/326 are implemented in. Embodiments of the present invention may also be implemented in non-planar structures. For example, the workpiece 122, 222, or 322 may be patterned before forming the template 124, 224, 324 of the material layer 124/126, 224/226, and 324/326 over the workpiece 122, 222, or 322. Patterning the workpiece 122, 222, or 322 may comprise forming at least one recess in the workpiece 122, 222, or 322 and forming the template 124, 224, 324 may comprise forming the template 124, 224, 324 on sidewalls and a bottom surface of the at least one recess in the workpiece 122, 222, or 322, for example. Patterning the workpiece 122, 222, or 322 may comprise forming at least one protruding feature on the workpiece 122, 222, or 322, and forming the template 124, 224, 324 may comprise forming the template 124, 224, 324 over sidewalls and a top surface of the at least one protruding feature of the workpiece 122, 222, or 322, for example.

A dynamic random access memory (DRAM) is a memory device that may be used to store information. A DRAM cell in a memory array typically includes two elements: a storage capacitor formed in a recess in the workpiece and an access transistor. Data may be stored into and read out of the storage capacitor by passing a charge through the access transistor and into the capacitor. High k dielectric materials are typically used as an insulating material in the storage capacitor of DRAM cells.

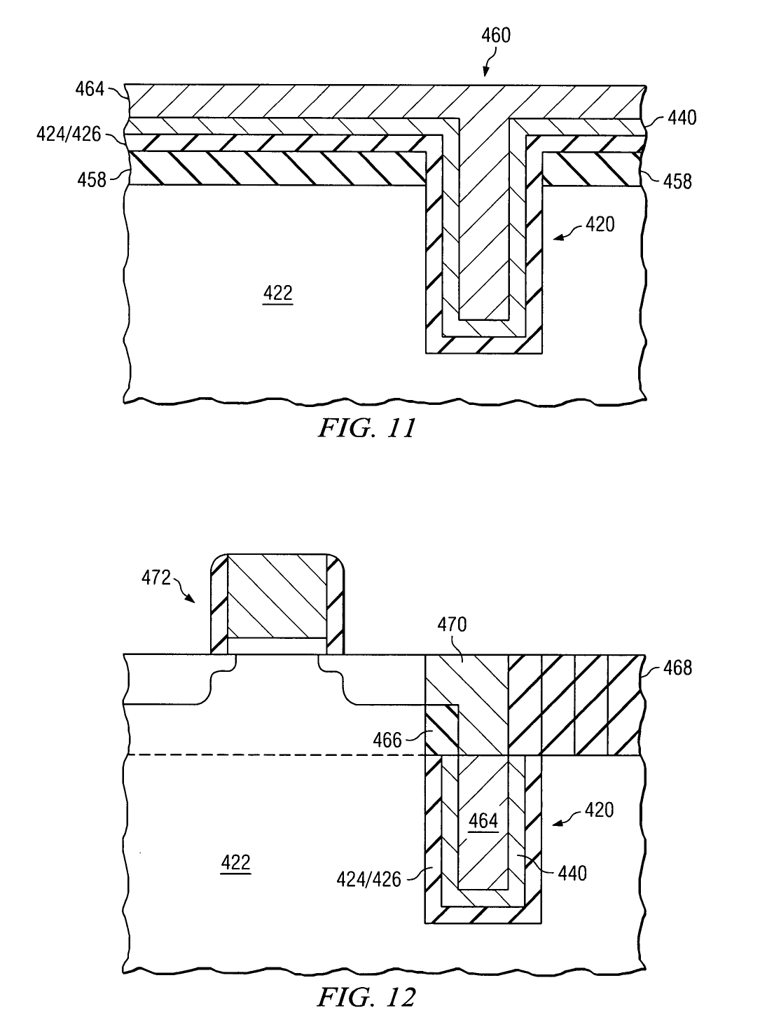

FIGS. 11 and 12 show cross-sectional view of a semiconductor device 420 at various stages of manufacturing, wherein the novel material layer 424/426 of embodiments of the present invention is implemented in a DRAM structure as a high k dielectric material. To form a DRAM memory cell comprising a storage capacitor utilizing the material layer 424/426 of embodiments of the present invention, a sacrificial material 458 comprising an insulator such as a hard mask material is deposited over a workpiece 422, and deep trenches 460 are formed in the sacrificial material 458 and the workpiece 422. The material layer 424/426 is formed using the novel methods described herein over the patterned sacrificial material 458, and an electrode material 440 is formed over the material layer 424/426, as shown. An additional electrode material 464 comprising polysilicon or other semiconductor or conductive material may be deposited over the electrode material 440 to fill the trenches 460, as shown in FIG. 11.

Next, excess amounts of materials 464, 440, and 424/426 are removed from over the top surface of the workpiece 422, e.g., using a chemical mechanical polish (CMP) process and/or etch process. The materials 464, 440, and 424/426 are also recessed below the top surface of the workpiece 422, for example. The sacrificial material 458 is also removed, as shown in FIG. 12.

An oxide collar 466 may be formed by thermal oxidation of exposed portions of the trench 460 sidewalls. The trench 460 may then be filled with a conductor such as polysilicon 470. Both the polysilicon 470 and the oxide collar 466 are then etched back to expose a sidewall portion of the workpiece 422 which will form an interface between an access transistor 472 and the capacitor formed in the deep trench 460 in the workpiece 422, for example.

After the collar 466 is etched back, a buried strap may be formed at 470 by deposition of a conductive material, such as doped polysilicon. Regions 464 and 470 comprising polysilicon are preferably doped with a dopant such as arsenic or phosphorus, for example. Alternatively, regions 464 and 470 may comprise a conductive material other than polysilicon (e.g., a metal).

The strap material 470 and the workpiece 422 may then be patterned and etched to form STI regions 468. The STI regions 468 may be filled with an insulator such as an oxide deposited by a high density plasma process (i.e., HDP oxide). The access transistor 472 may then be formed to create the structure shown in FIG. 12.

The workpiece 422 proximate the material layer 424/426 lining the deep trench 460 comprises a first capacitor plate, the material layer 424/426 comprises a capacitor dielectric, and materials 440 and 464 comprise a second capacitor plate of the deep trench storage capacitor of the DRAM memory cell. The access transistor 472 is used to read or write to the DRAM memory cell, e.g., by the electrical connection established by the strap 470 to a source or drain of the transistor near the top of the deep trench 460, for example.

Again, the novel ALD processes may be used to form other material layers of the DRAM memory cell shown in FIGS. 11 and 12, such as portions of the capacitor plate materials, for example, not shown.

Embodiments of the present invention may be implemented in other structures that require thin, conformal materials. For example, the material layers 124/126, 224/226, 324/326, and 424/426 may be implemented in planar transistors, vertical transistors, planar capacitors, stacked capacitors, vertical capacitors, deep or shallow trench capacitors, and other devices. Embodiments of the present invention may be implemented in stacked capacitors where both plates reside above a substrate or workpiece 122, 222, 322, or 422, for example.

In accordance with embodiments of the present invention, Frank-Van der Merve two dimensional (2D) layer by layer type of growth using ALD processes is achieved, forming a complete, initial saturated template 124, 224, 324, and 424 on all surfaces, particularly at the bottom of high aspect ratio structures such as the deep trenches 460 for the storage capacitor shown in FIGS. 11 and 12. In addition, in accordance with embodiments of the present invention, surface preparation is preferably optimized, and defectivity, particularly point, line and surface defects in the silicon of the workpiece 122, 222, 322, and 422 is preferably minimized. The precursors used in the ALD processes in some embodiments preferably comprise a low steric hindrance factor, in order to achieve complete surface coverage, for example. Furthermore, it is most preferable that a range of other properties are kept within specific ranges during the ALD processes described herein, such as vapor pressure of the precursor to ensure adequate throughput, an optimized sticking coefficient, thermal stability, and purity, as examples.

Embodiments of the present invention comprise novel methods of forming the material layers 124/126, 224/226, 324/326, and 424/426 described herein. Embodiments of the present invention also include semiconductor devices including the material layers 124/126, 224/226, 324/326, and 424/426 described herein.

Embodiments of the present invention also include tools for processing semiconductor devices using the methods described herein. The tools preferably include a reactor adapted to affect a semiconductor device using ALD cycles at a first, higher pressure and ALD cycles at a second, lower pressure, for example. A reactor or tool may be altered in order to be able to process semiconductor wafers at higher pressures, for example.

Advantages of embodiments of the present invention include providing novel methods of forming material layers 124/126, 224/226, 324/326, and 424/426 having improved film uniformity with substantially continuous, island-free coverage. Improved uniformity of a material layer 124/126 may be achieved due to the improved nucleation of the template 124, 224, 324, and 424, for example. Surface coverage of films formed using ALD is maximized by facilitating a Frank-Van der Merve type of growth of the template 124, 224, 324, and 424. Complete saturation during the template formation may be achieved, ensuring excellent step coverage (e.g., of greater than 90%), even in very high aspect ratio patterned wafers 122, 222, 322, and 422, in applications such as trench or stacked capacitors used in DRAM technology, which may have aspect ratios as high as about 50:1 or greater, for example.

Because the initial template 124, 224, 324, 424 formation is performed at a higher pressure, the reactants and precursors of the ALD cycles used to form the template 124, 224, 324, 424 are forced to move deeply into features such as trenches or between protruding features, forming a uniform coating of the template 124, 224, 324, 424, even in high aspect ratio features. Embodiments of the present invention resulting in enhanced filling of trenches, for example. The templates 124, 224, 324, 424 provide an excellent starting surface with improved nucleation, which improves the subsequent formation of layers 126, 226, 326, 426. The novel multi-pressure ALD cycles used to form the material layers 124/126, 224/226, 324/326, and 424/426 result in improved semiconductor devices having increased yields and improved performance.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of forming a material layer, the method comprising:
providing a semiconductor wafer;
forming a first portion of a material layer over the semiconductor wafer at a first pressure; and
forming a second portion of the material layer over the first portion of the material layer at a second pressure, the second pressure being less than the first pressure.

2. The method according to claim 1, wherein forming the first portion of the material layer comprises using an atomic layer deposition (ALD) process or wherein forming the second portion of the material layer comprises using an ALD process.

3. The method according to claim 1, wherein forming the first portion and the second portion of the material layer comprise forming the first portion and the second portion of the material layer wherein the first pressure is greater than the second pressure by about ten times (10×) or more.

4. The method according to claim 1, wherein forming the first portion of the material layer comprises forming a template for the second portion of the material layer.

5. The method according to claim 1, further comprising forming at least one third portion of the material layer over the second portion of the material layer.

6. The method according to claim 5, wherein forming the at least one third portion of the material layer comprises forming the at least one third portion of the material layer at a third pressure, the third pressure being less than the second pressure.

7. A method of processing a semiconductor device, the method comprising:
providing a workpiece;
forming a template of a material layer over the workpiece using at least one first atomic layer deposition (ALD) process having a first pressure; and
forming the material layer over the template using at least one second ALD process having a second pressure, the first pressure being greater than the second pressure.

8. The method according to claim 7, wherein forming the template and forming the material layer comprise forming an insulator or a conductor.

9. The method according to claim 7, further comprising patterning the workpiece, before forming the template of the material layer over the workpiece.

10. The method according to claim 9, wherein patterning the workpiece comprises forming at least one recess in the workpiece, wherein forming the template comprises forming the template on sidewalls and a bottom surface of the recess; or wherein patterning the workpiece comprises forming at least one protruding feature on the workpiece, wherein forming the template comprises forming the template over sidewalls and a top surface of the at least one protruding feature.

11. The method according to claim 7, wherein forming the material layer over the template comprises forming a substantially continuous, conformal material layer over the workpiece, and wherein the material layer is island-free.

12. The method according to claim 7, wherein forming the template of the material layer over the workpiece using the at least one first ALD process comprises using an at least one first ALD process having a first pressure of about 0.15 to 100 Torr.

13. A method of manufacturing a semiconductor device, the method comprising:
providing a workpiece; and
forming a material layer over the workpiece, wherein forming the material layer comprises forming at least one first portion of the material layer using a first atomic layer deposition (ALD) process and forming at least one second portion of the material layer over the at least one first portion of the material layer using a second ALD process, the first ALD process having a higher pressure than the second ALD process.

14. The method according to claim 13, wherein forming the at least one first portion of the material layer or forming the at least one second portion of the material layer comprises forming at least one sub-monolayer, at least one monolayer, or a plurality of monolayers of the material layer.

15. The method according to claim 13, wherein forming the at least one first portion of the material layer and forming the at least one second portion of the material layer comprise using a plurality of ALD processes having successively lower pressures.

16. The method according to claim 15, wherein each of the plurality of ALD processes forms a layer having a thickness of about 0.5 to 10 Angstroms.

17. The method according to claim 13, wherein providing the workpiece comprises providing at least one first workpiece, the at least one first workpiece comprising at least one planar region, further comprising examining the surface of the at least one first portion of the material layer over the at least one planar region, after forming the at least one first portion of the material layer.

18. The method according to claim 17, wherein examining the surface of the at least one first portion of the material layer comprises using low energy ion spectroscopy (LEIS), medium energy ion spectroscopy (MEIS), or X-ray fluorescence (XRF) to determine if the at least one first portion of the material layer completely covers the at least one first workpiece in the at least one planar region.

19. The method according to claim 17, further comprising forming at least one additional layer of the at least one first portion of the material layer, if examining the surface reveals that the at least one first workpiece is not completely covered with the at least one first portion of the material layer.

20. The method according to claim 17, further comprising providing at least one second workpiece, the at least one second workpiece comprising a patterned wafer, further comprising forming the at least one first portion of the material layer over the at least one second workpiece, wherein a number of ALD cycles of the first atomic layer deposition (ALD) process is altered based on the examination of the surface of the at least one first portion of the material layer of the at least one first workpiece and/or based on dimensions of a topography of the patterned at least one second workpiece.

21. A method of manufacturing a semiconductor device, the method comprising:
providing a workpiece; and
forming an insulating layer or conductive layer over the workpiece, wherein forming the insulating layer or the conductive layer over the workpiece comprises forming at least one first portion of a material layer using a plurality of atomic layer deposition (ALD) cycles at a first pressure and forming at least one second portion of the material layer over the first portion of the material layer using a plurality of ALD cycles at a second pressure, the first pressure being greater than the second pressure.

22. The method according to claim 21, wherein forming the insulating layer or conductive layer comprises forming a conductive layer comprising a gate electrode of a transistor or an insulating layer comprising a gate dielectric of a transistor, and wherein the transistor further comprises a source region disposed in the workpiece, a drain region disposed in the workpiece, and a channel region disposed between the source region and the drain region in the workpiece.

23. The method according to claim 21, wherein forming the insulating layer or conductive layer comprises forming an insulating layer comprising a capacitor dielectric; a conductive layer comprising a first conductive layer comprising a first capacitor plate disposed beneath a capacitor dielectric; or a conductive layer comprising a second conductive layer comprising a second capacitor plate disposed over a capacitor dielectric.

24. The method according to claim 23, wherein the semiconductor device comprises a dynamic random access memory (DRAM) cell comprising a storage capacitor, the storage capacitor comprising a first capacitor plate comprising a portion of the workpiece of the semiconductor device, a capacitor dielectric comprising the insulating layer, or a second capacitor plate comprising the conductive layer adjacent to the insulating layer, and wherein the DRAM cell further comprises a transistor formed in the workpiece coupled to the first plate of the storage capacitor.

25. The method according to claim 23, wherein forming the insulating layer comprises forming a dielectric material having a single element combined with an oxide, a nitride, or both and oxide or a nitride, or a plurality of elements combined with an oxide, a nitride, or both an oxide and a nitride.

26. A semiconductor device manufactured in accordance with the method of claim 21.

27. A tool for processing a semiconductor device using the method according to claim 21, wherein the tool includes a reactor adapted to affect the semiconductor device using the plurality of atomic layer deposition (ALD) cycles at the first pressure and the plurality of ALD cycles at the second pressure.
